(19) United States
(12) Patent Application Publication
(10) Pub. No.: US 2023/0375917 A1
(43) Pub. Date: Nov. 23, 2023

(54) METHOD AND DEVICE FOR CORRECTING PLACEMENT ERROR OF PHOTOMASK

(71) Applicant: CHANGXIN MEMORY TECHNOLOGIES, INC., Hefei City, Anhui (CN)

(72) Inventors: Xiuxuan ZHANG, Hefei City, Anhui (CN); Zhineng KONG, Hefei City, Anhui (CN)

(73) Assignee: CHANGXIN MEMORY TECHNOLOGIES, INC., Hefei City, Anhui (CN)

(21) Appl. No.: 17/628,484

(22) PCT Filed: Aug. 13, 2021
(86) PCT No.: PCT/CN2021/112416

§ 371 Date: Jul. 7, 2022

(30) Foreign Application Priority Data
Jan. 4, 2021 (CN) 202110004432.X

(51) Int. Cl. G03F 1/74; G03F 1/86; G03F 1/70; G03F 7/00

(52) U.S. Cl. CPC G03F 1/74; G03F 1/86; G03F 1/70; G03F 7/70433

(57) ABSTRACT

A method and a device for correcting a placement error of a photomask are provided. The method includes: acquiring an exposure offset during a wafer exposure after photomask manufacture is completed, wherein the wafer exposure is a process of forming a circuit pattern on a wafer surface by exposure; and determining a compensation offset for subsequent photomask manufacture according to the exposure offset, to correct a placement error of a photomask, wherein the compensation offset and the exposure offset are vector values that are equal in value and opposite in direction. The method and device for correcting the placement error of the photomask provided in the embodiments of the present disclosure can reduce an overlay error existing in a photolithography process of a semiconductor device by correcting a placement error of a photomask.

### CROSS-REFERENCE TO RELATED APPLICATION

The present disclosure claims priority from Chinese Application No. 202110004432.X filed on Jan. 4, 2021 and entitled “Method and Device for Correcting Placement Error of Photomask”, the entirety of which is herein incorporated by reference.

### TECHNICAL FIELD

The present disclosure relates to technologies of semiconductor manufacturing, and more particularly, to a method and a device for correcting a placement error of a photomask.

### BACKGROUND

In a manufacturing process of a semiconductor device, a photolithography process is a critical process operation. The photolithography process includes the operations of wafer surface cleaning and pre-baking, priming, spin-on photoresist coating, soft baking, alignment and exposure, post exposure baking, hard baking, etching, etc., so as to form a circuit pattern with a precise dimension on the wafer surface. In a photolithography process, multiple exposures need to be performed, wherein one exposure is used for manufacturing a photomask, and may also be understood as photomask exposure. In the photomask exposure process, a required pattern is engraved on a quartz substrate by an electron beam, and the acquired quartz substrate with the engraved pattern is the required photomask. In another exposure, after the required photomask is acquired, an ultraviolet light beam passes through the photomask to irradiate the pattern engraved on the photomask onto the photoresist on the wafer surface, so as to form a specific circuit pattern.

However, as many layers of circuit patterns need to be formed in an overlapped manner in the manufacturing process of the semiconductor device, it is necessary to perform photolithography on the wafer surface for multiple times. Furthermore, during the photolithography, the alignment precision between each layer and the previous or next layer needs to be ensured. If the alignment precision exceeds an allowed range, it may cause that the entire semiconductor device cannot complete expected functions. However, in practical operations, factors of the scanner (also referred to as exposure machine or exposure platform), the photoresist or the photomask may all introduce overlay errors during the photolithography, that is, a positioning error exists between a circuit pattern formed by exposure of a previous layer and a circuit pattern formed by exposure of a next layer. More attention needs to be paid to the phenomenon of an overlay error generated by the placement error of the photomask during the photomask exposure. i.e., the deviation between the actual position of the pattern on the photomask and the expected position of the pattern on the photomask.

Therefore, how to reduce an overlay error in a photolithography process of a semiconductor device by correcting a displacement error of a photomask is still a problem to be solved urgently.

### SUMMARY

The embodiments of the present disclosure provide a method and a device for correcting a placement error of a photomask. An exposure offset during a wafer exposure is acquired to deduce a compensation offset for subsequent photomask manufacture, so that an inherent offset in the photomask manufacture can be canceled, thereby correcting a placement error of the photomask. By correcting the placement error of the photomask, an overlay error in a photolithography process of a semiconductor device is reduced.

In one aspect, the embodiments of the present disclosure provide a method for correcting a placement error of a photomask, including:
acquiring an exposure offset during the wafer exposure after photomask manufacture is completed, wherein the wafer exposure is a process of forming a circuit pattern on a wafer surface by exposure; and
determining a compensation offset for subsequent photomask manufacture according to the exposure offset, to correct a placement error of a photomask,
wherein the compensation offset and the exposure offset are vector values that are equal in value and opposite in direction.

According to the method for correcting the placement error of the photomask provided in the present embodiment, an exposure offset during a wafer exposure can be acquired to deduce a compensation offset for subsequent photomask manufacture, so that an inherent offset in the photomask manufacture can be canceled, thereby correcting a placement error of a photomask. In this way, the position of the circuit pattern acquired by subsequent wafer exposure performed after the photomask manufacture is completed is consistent with a preset pattern position, thereby solving the problem that the expected performance of the semiconductor device cannot be achieved due to the placement error of the photomask.

In another aspect, the embodiments of the present disclosure provide a method for manufacturing a photomask, applied to a scanner for manufacturing the photomask, and including:
receiving a compensation offset when a photomask is exposed, wherein the compensation offset and an exposure offset during a wafer exposure are vector values that are equal in value and opposite in direction, a wafer exposure is performed after a previous photomask manufacture is completed, and the wafer exposure is a process of forming a circuit pattern on a wafer surface by exposure, and
manufacturing a photomask by taking the compensation offset as an exposure reference.

According to the method provided in this embodiment, the compensation offset can be determined when forming any layer of circuit pattern on the wafer surface, and used for correcting a placement error of the photomask for the next layer of circuit pattern, and the placement of the photomask during the photomask manufacture can be set based on the compensation offset, so as to eliminate the placement error of the photomask and reduce an overlay error existing in a photolithography process of a semiconductor device.

In another aspect, the embodiments of the present disclosure provide a device for correcting a placement error of a photomask, including:
an acquisition module, configured to acquire an exposure offset during a wafer exposure after photomask manufacture is completed, wherein the wafer exposure is a process of forming a circuit pattern on a wafer surface by exposure; and
a determination module, configured to determine a compensation offset for subsequent photomask manufacture according to the exposure offset, to correct a placement error of a photomask,
wherein the compensation offset and the exposure offset are vector values that are equal in value and opposite in direction.

In another aspect, the embodiments of the present disclosure provide a device for manufacturing a photomask, including:
a receiving module, configured to receive a compensation offset for photomask manufacture, wherein the compensation offset and an exposure offset during a wafer exposure are vector values that are equal in value and opposite in direction, a wafer exposure is performed after a previous photomask manufacture is completed, and the wafer exposure is a process of forming a circuit pattern on a wafer surface by exposure; and
an exposure module, configured to manufacture a photomask by taking the compensation offset as an exposure reference.

In another aspect, the embodiments of the present disclosure provide a terminal device, including a memory, a processor and a transceiver, wherein the memory is configured to store instructions, the transceiver is configured to communicate with another device, and the processor is configured to execute the instructions stored in the memory, so that the terminal device executes the method for correcting the placement error of the photomask according to the first aspect.

In another aspect, the embodiments of the present disclosure provide a computer readable storage medium, wherein the computer readable storage medium stores a computer executable instruction, and the computer is configured to execute, when executing the computer executable instruction, the method for correcting the placement error of the photomask according to the first aspect.

In another aspect, the embodiments of the present disclosure provide a computer program product, including a computer program, wherein the computer program, when executed by a processor, causes the processor to implement the method for correcting the placement error of the photomask according to the first aspect.

### BRIEF DESCRIPTION OF THE DRAWINGS

FIG. 1 is a schematic diagram of an application scenario of a method for correcting a placement error of a photomask according to some embodiments of the present disclosure.

FIG. 2 is a flowchart of a method for correcting a placement error of a photomask according to embodiment I of the present disclosure.

FIG. 3 is a schematic diagram of a method for correcting a placement error of a photomask according to embodiment I of the present disclosure.

FIG. 4 is a flowchart of a method for correcting a placement error of a photomask according to embodiment II of the present disclosure.

FIG. 5 is a flowchart of a method for manufacturing a photomask according to embodiment III of the present disclosure.

FIG. 6 is a schematic diagram of a device for correcting a placement error of a photomask according to embodiment IV of the present disclosure.

FIG. 7 is a schematic diagram of a method for manufacturing a photomask according to embodiment V of the present disclosure.

FIG. 8 is a schematic diagram of a terminal device according to embodiment VI of the present disclosure.

FIG. 9 is a schematic diagram of a scanner according to embodiment VII of the present disclosure.

### DETAILED DESCRIPTION OF THE EMBODIMENTS

The exemplary embodiments are explained in more details below and are illustrated in the accompanying drawings. When the following description refers to the accompanying drawings, unless indicated otherwise, the same numbers in different drawings represent the same or similar elements. The embodiments described in the following exemplary embodiments do not represent all embodiments consistent with concept of the present disclosure. Rather, they are merely examples of devices and methods, as detailed in the appended claims, consistent with some aspects of the embodiments of the present disclosure.

A photolithography process is required in a manufacturing process of a semiconductor device, for example, the manufacturing of an integrated circuit or a chip. Taking an integrated circuit as an example, the integrated circuit is formed by overlapping multiple layers of circuit patterns, and photolithography needs to be performed on a wafer surface for multiple times in the manufacturing process. During the photolithography, alignment precision between each layer and a previous or next layer needs to be ensured. If the alignment precision exceeds an allowed range, it may cause that the entire semiconductor device cannot complete expected functions. However, among various factors affecting the alignment precision, special attention needs to be paid to the placement error of the photomask, i.e., the overlay error caused by the deviation between the actual pattern position of the photomask and the expected pattern position during photomask exposure.

The overly error is explained herein. Multiple exposures are needed when a layer of circuit pattern is formed on the wafer surface. The objective of photomask exposure is to acquire a required photomask. In the photomask exposure process, a required pattern is engraved on a quartz substrate by an electron beam, and the acquired quartz substrate with the engraved pattern is the required photomask. After the required photomask is acquired, wafer exposure is performed. Wafer exposure refers to a process that an ultraviolet light beam passes through the photomask to irradiate the surface of a wafer, so as to reduce the engraved pattern on the photomask to the wafer surface, to form a specific circuit pattern on the wafer surface. The photomask exposure will generate a placement error of a photomask, and the photomask placement error will be superimposed during the subsequent wafer exposure, forming a layer of circuit pattern having an overlay error. When the next layer of circuit pattern is etched, another overlay error will be formed due to the placement error of the photomask. The superimpose of the overlay error, which is generated when the multiple layers of circuit patterns are etched, affects the alignment precision of the multiple layers of circuit patterns, thereby affecting the performance of the semiconductor device.

Based on this, the embodiments of the present disclosure provide a method and device for correcting a placement error of a photomask. According to the solution, an exposure offset during a wafer exposure is acquired to deduce a compensation offset for subsequent photomask manufacture. When a scanner for manufacturing the photomask manufactures a photomask according to the compensation offset, the offset for the photomask exposure is set to be equal to the compensation offset, so that the purpose of canceling an inherent offset in the photomask manufacture is achieved, thereby correcting the inherent photomask placement error. In this way, the position of the circuit pattern acquired by subsequent wafer exposure performed after the photomask manufacture is completed is consistent with a preset pattern position, thereby eliminating the overlay error by correcting the placement error of the photomask.

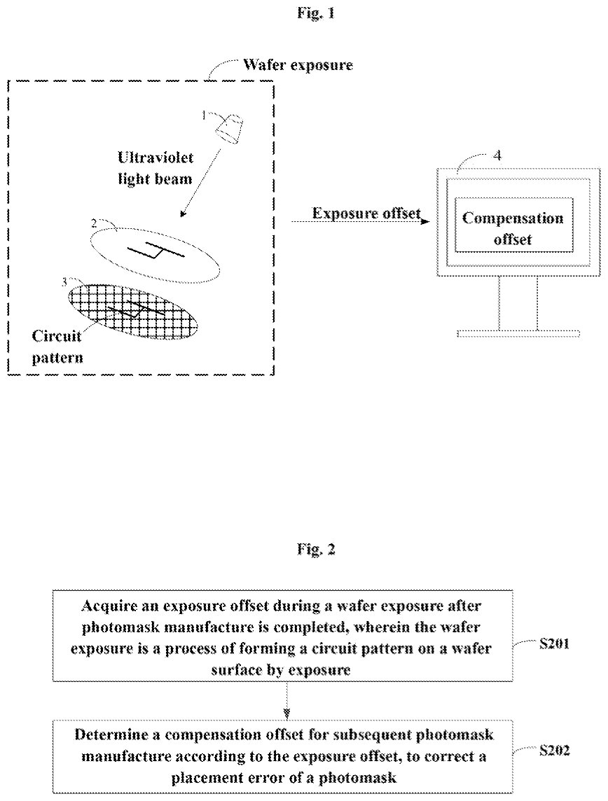

The method for correcting the placement error of the photomask provided in the embodiments of the present disclosure is applied to a terminal device. The terminal device is, for example, a dedicated laboratory computer, a wafer scanner including a processor, a server, etc. FIG. 1 is a schematic diagram of an application scenario of a method for correcting a placement error of a photomask according to some embodiments of the present disclosure. The process of wafer exposure is shown in the left portion of FIG. 1, wherein a photomask 2 is a manufactured photomask, a light source 1 emits an ultraviolet light beam, and the ultraviolet light beam passes through the photomask 2 to expose the wafer surface 3. A preset circuit pattern has been formed on the photomask 2, the circuit pattern can be reversely printed on the wafer surface 3 by the ultraviolet light beam, and then the circuit pattern can be formed on the wafer surface 3 by etching. For FIG. 1, it should be noted that, the photomask 2 is separated from the wafer surface 3 in FIG. 1, but such illustration does not limit the distance between the photomask 2 and the wafer surface 3.

The right portion of FIG. 1 shows a terminal device 4. The terminal device 4 can acquire the exposure offset during a wafer exposure, and output the compensation offset for subsequent photomask manufacture. The compensation offset can be displayed on the screen of the terminal device 4, or can be transmitted to an electronic device at the worker side in an available communication manner, or can be notified to the worker in other manners.

Refer to FIG. 2, embodiment I of the present disclosure provides a method for correcting a placement error of a photomask, including the following operations S201 and S202.

In S201, an exposure offset during a wafer exposure after photomask manufacture is completed is acquired, wherein the wafer exposure is a process of forming a circuit pattern on a wafer surface by exposure.

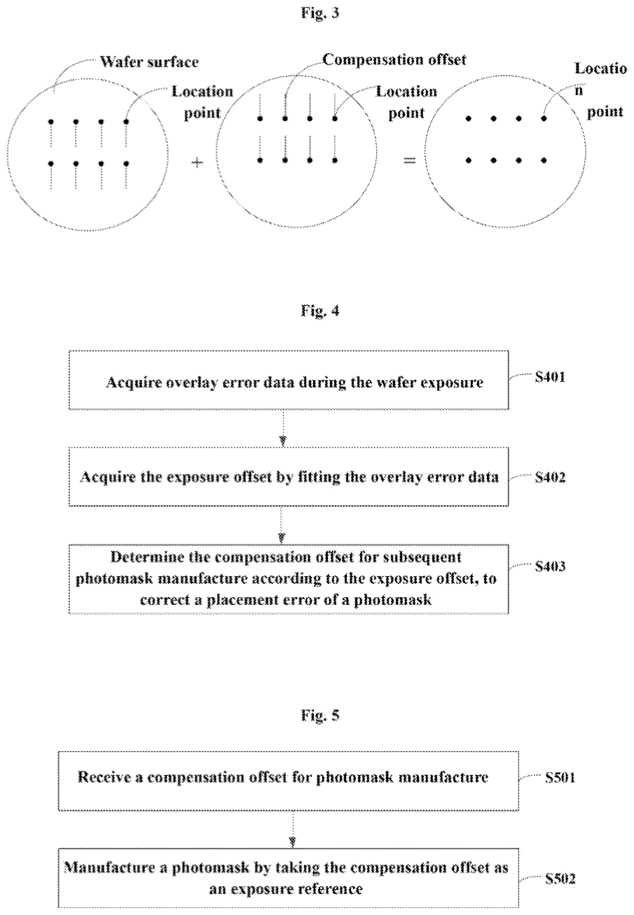

As shown in FIG. 3, the wafer has a plurality of pattern areas, each pattern area including a plurality of location points, that is, the wafer has a plurality of location points. The exposure offset refers to an offset of each location point on the wafer in an actual exposure process. In this embodiment, it is defaulted that the offset of each location point on the wafer is equal, and the exposure offset refers to the offset of each location point on the wafer. A wafer exposure is performed after the photomask exposure, i.e. after the completion of the photomask manufacture, and the offset of the location point is caused by a placement error of the photomask during the photomask manufacture, therefore the exposure offset can directly reflect the inherent offset in photomask exposure.

In S202, a compensation offset for subsequent photomask manufacture is determined according to the exposure offset, to correct a placement error of a photomask.

Refer to FIG. 3, the compensation offset is used for reversely cancelling and compensating the inherent offset of each location point during the photomask manufacture. In this embodiment, in the case of ignoring other influence factors, the inherent offset of each location point is considered to be equal to the exposure offset. That is, the compensation offset and the exposure offset are vector values that are equal in value and opposite in direction. Since there are many location points on the wafer, the compensation offset refers to a vector that compensates for the location offset of each location point on the wafer.

For example, when the wafer is subjected to the wafer exposure after the photomask exposure is completed, the exposure offset of any location point A on the wafer surface is Location A, OVL(X)a nm, OVL(Y)b nm, and the compensation offset determined according to the exposure offset is Location A, OVL(X)-a nm, OVL(Y)-b nm, wherein X and Y respectively represent two direction axes on a two-dimensional plane, the two-dimensional plane including an origin which is an intersection point of an X axis and a Y axis, then a represents an offset of the location point A on a positive direction of the X axis, b represents an offset of the location point A on a positive direction of the Y axis, and nm is a unit of measurement of length i.e. nanometer.

After learning the compensation offset, the worker can set the compensation offset on a scanner for manufacturing the photomask, so that the photomask is deviated by the compensation offset when manufacturing the photomask again, so as to cancel the inherent offset in manufacturing the photomask, in this way, the offset of the location point A in the example above can be expressed as Location A, OVL(X) 0 nm, OVL(Y) 0 nm. As shown in FIG. 3, there is no offset in positions of all the location points on the wafer surface acquired after the wafer exposure is finally performed again.

Therefore, in the method for correcting the placement error of the photomask provided in this embodiment, an exposure offset during a wafer exposure is acquired to deduce a compensation offset for subsequent photomask manufacture, so that an inherent offset in the photomask manufacture can be canceled, thereby correcting a placement error of a photomask. In this way, the position of the circuit pattern acquired by subsequent wafer exposure performed after the photomask manufacture is completed is consistent with a preset pattern position, thereby solving the problem that the expected performance of the semiconductor device cannot be achieved due to the placement error of the photomask.

Refer to FIG. 4, embodiment II of the present disclosure provides a method for correcting a placement error of a photomask, including the following operations S401 to S403.

In S401, overlay error data during the wafer exposure is acquired.

As described in embodiment I with respect to the exposure offset and the compensation offset, the overlay error data may also be understood as a vector value. Taking the location point B on the wafer surface as an example, the position of the location point B may be expressed as Location B, OVL(X)c nm, OVL(Y)d nm, wherein c represents the offset of point A in the positive direction of the X axis, and d represents the offset of point A in the positive direction of the Y axis.

In S402, the exposure offset is acquired by fitting the overlay error data.

The overlay error data includes overlay error data for a plurality of location points on the wafer surface, i.e., overlay error data for a plurality of location points, and the overlay error data for each location point may or may not be equal. The fitting referred to in operation S402 can be understood as a process of minimizing the difference between the overlay error data for all the location points on the wafer surface, such that the overlay error data for each location point is approximately equal. After fitting processing is performed, the offset error of each location point is acquired as the exposure offset.

In S403, a compensation offset for subsequent photomask manufacture is determined according to the exposure offset, to correct a placement error of a photomask.

For specific implementation of this operation, reference is made to the description of operation S202 in embodiment I shown in FIG. 2, and details are not described herein again.

According to the method for correcting the placement error of the photomask provided in this embodiment, the location offset, i.e. the overlay error data, of all the location points on the wafer is fitted, and it is considered that the location offset of each location point is approximately equal to the exposure offset. The compensation offset for subsequent photomask manufacture is determined according to the exposure offset, so as to cancel the inherent offset in the photomask manufacture, and correct the placement error of the photomask. By virtue of the solution provided in embodiment I, the method for correcting the placement error of the photomask in this embodiment can solve the problem that the expected performance of the semiconductor device cannot be achieved due to the placement error of the photomask.

Refer to FIG. 5, embodiment III of the present disclosure provides a method for manufacturing a photomask, which is applied to a scanner for manufacturing the mask. The method for manufacturing a photomask includes the following operations S501 and S502.

In S501, a compensation offset for photomask manufacture is received.

The compensation offset and the exposure offset during the wafer exposure are vector values that are equal in value and opposite in direction. A wafer exposure is performed after a previous photomask manufacture is completed, and the wafer exposure is a process of exposing the wafer surface to form a circuit pattern. As described in operation S201 of embodiment I, it is also default in embodiment III that an offset of each location point on the wafer is equal, and the exposure offset is equal to an offset of any location point on the wafer. The offset of the location point is caused by a placement error of a photomask, and the compensation offset is used for performing reverse offset compensation on the offset of any location point during the photomask manufacture.

In S502, a photomask is manufactured by taking the compensation offset as an exposure reference.

Manufacturing a photomask by taking the compensation offset as an exposure reference refers to that when a scanner is used to manufacture a photomask, the placement position of the photomask is controlled to be offset by the compensation offset during the photomask manufacture, so as to avoid the location offset of any location point caused when wafer exposure is performed again by means of the photomask.

Assuming that when wafer exposure is performed after photomask manufacture is completed, the exposure offset of the location point C on the wafer surface is Location C, OVL(X)e nm and OVL(Y)f nm, then the compensation offset determined according to exposure data from the wafer end, i.e. data during a wafer exposure, is Location C, OVL(X)-e nm, OVL(Y)-f nm. The Location C, OVL(X)-e nm, OVL(Y)-f nm are set as an exposure reference for the subsequent exposure of the location point C, and the offset of the location point C after a circuit pattern is finally formed can be expressed as Location C. OVL(X)O nm, OVL(Y)O nm. As described in embodiment I, X and Y respectively represent two direction axes on a two-dimensional plane, the two-dimensional plane including an origin which is an intersection point of an X axis and a Y axis; then e represents an offset of the location point C in the positive direction of the X axis, f represents an offset of the location point C in the positive direction of the Y axis, -e represents an offset of the location point C in the negative direction of the X axis, and -f represents an offset of the location point C in the negative direction of the Y axis.

In a manufacturing process of a semiconductor device, multiple layers of circuit patterns need to be superimposed on a wafer surface, and each layer of circuit patterns needs to be subjected to a wafer exposure process for multiple times. In this embodiment, it can be understood that, when the first layer of circuit pattern is formed on the wafer surface, the exposure offset of the first layer of circuit pattern during a wafer exposure is acquired, and a compensation offset for manufacturing the photomask, that needs to be set on the scanner for manufacturing the photomask when the next layer of circuit pattern is etched, is determined according to the exposure offset. According to the method provided in this embodiment, the compensation offset can be determined when forming any layer of circuit pattern on the wafer surface, and used for correcting a placement error of the photomask for the next layer of circuit pattern, and the placement of the photomask during the photomask manufacture can be set based on the compensation offset, so as to eliminate the placement error of the photomask and reduce an overlay error existing in a photolithography process of a semiconductor device.

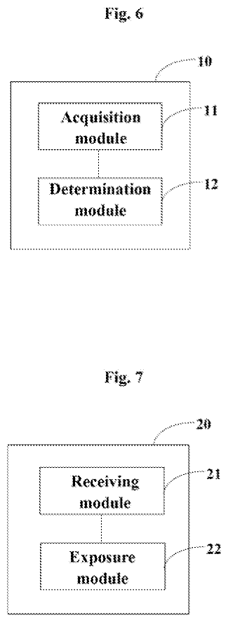

Refer to FIG. 6, embodiment IV of the present disclosure provides a device 10 for correcting a placement error of a photomask, including:
an acquisition module 11, configured to acquire an exposure offset during a wafer exposure after photomask manufacturing is completed, wherein the wafer exposure is a process of forming a circuit pattern on a wafer surface by exposure; and
a determination module 12, configured to determine a compensation offset for subsequent photomask manufacture according to the exposure offset, to correct a placement error of a photomask, wherein the compensation offset and the exposure offset are vector values that are equal in value and opposite in direction.

The acquisition module 11 is configured to acquire overlay error data during the wafer exposure. The exposure offset is acquired by fitting the overlay error data. The overlay error data includes overlay error data for all location points on a wafer.

According to the device 10 for correcting a placement error of a photomask provided in the present embodiment, an exposure offset during a wafer exposure can be acquired to deduce a compensation offset for subsequent photomask manufacture, so that an inherent offset in the photomask exposure can be canceled, thereby correcting a placement error of a photomask. Specifically, according to the device for correcting a placement error of a photomask provided in this embodiment, the location offset, i.e. the overlay error data, of all the location points on the wafer is fitted and it is considered that the location offset of each location point is approximately equal to the exposure offset. A compensation offset for the subsequent photomask exposure is determined according to the exposure offset, so as to cancel the inherent offset in the photomask exposure, and correct the placement error of the photomask. By virtue of the solution provided in embodiment I, the device for correcting a placement error of a photomask in this embodiment can solve the problem that the expected performance of the semiconductor device cannot be achieved due to the placement error of the photomask.

Refer to FIG. 7, embodiment V of the present disclosure provides a device 20 for manufacturing a photomask, including:
a receiving module 21, configured to receive a compensation offset for photomask manufacture, wherein the compensation offset and the exposure offset during the wafer exposure are vector values that are equal in value and opposite in direction, a wafer exposure is performed after a previous photomask manufacture is completed, and the wafer exposure is a process of exposing the wafer surface to form a circuit pattern; and
an exposure module 22, configured to manufacture a photomask by taking the compensation offset as an exposure reference.

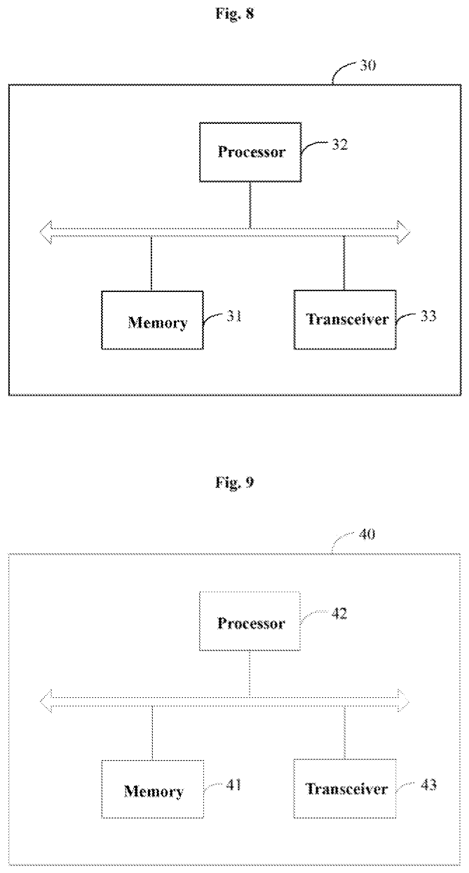

Refer to FIG. 8, embodiment VI of the present disclosure provides a terminal device 30, including a memory 31, a processor 32, and a transceiver 33. The memory 31 is configured to store an instruction, the transceiver 33 is configured to communicate with another device, and the processor 32 is configured to execute the instruction stored in the memory 31, so that the terminal device 30 executes the method for correcting the placement error of the photomask provided in the embodiment shown in FIG. 2 or FIG. 4. Specific implementations and technical effects are similar, and are not further described herein.

Refer to FIG. 9, embodiment VII of the present disclosure provides a scanner 40, which includes a memory 41, a processor 42, and a transceiver 43. The memory 41 is configured to store instructions, the transceiver 43 is configured to communicate with another device, and the processor 42 is configured to execute the instruction stored in the memory 41, so that the scanner 40 executes the method for manufacturing the photomask provided in the embodiment shown in FIG. 5. Specific implementations and technical effects are similar, and details are not described herein again.

The embodiment of the present disclosure provides a computer readable storage medium, the computer readable storage medium stores a computer executable instruction, and the computer executable instruction, when executed by a processor, causes the processor to implement the method for correcting the placement error of the photomask according to any one of the above embodiments. The embodiment of the present disclosure provides a computer program product, including a computer program. The computer program implements, when being executed by a processor, the method for correcting the placement error of the photomask provided in any one of the above embodiments.

It should be noted that the computer readable storage medium may be a read-only memory (ROM), a programmable read-only memory (PROM), an erasable programmable read-only memory (EPROM), an electrically erasable programmable read-only memory (EEPROM), a ferromagnetic random access memory (FRAM), a flash memory, a magnetic surface memory, an optical disc, or a compact disc read-only memory (CD-ROM); and may also be various electronic devices, such as a mobile phone, a computer, a tablet device and a personal digital assistant including one or any combination of the foregoing memories.

Through the above description of the embodiments, it should be clearly appreciated by the person skilled in the art that the method according to the embodiments may be implemented by means of software in connection with the required universal hardware platform, and of course, can also be implemented by hardware, but in many cases the former is a more preferred implementation. Without any further limitation, when an element is defined by the phrase “including one . . . ”, it is not excluded that additional elements the same as the element exist in the process, method, article or device that includes the element.

The sequence numbers of the embodiments of the present disclosure are only for the descriptive purpose rather than represent the relative merits of the embodiments.

The present disclosure is described by referring to flowchart and/or block diagram of the method, the device (system), and the computer program product according to the embodiments of the present disclosure. Based on this understanding, the essence of the techniques or the contributions to current technologies under the present disclosure may be implemented in the form of software products. Such software product may be stored in a storage medium (such as a ROM/RAM, a magnetic disk, or an optical disk), and includes several instructions for causing a terminal device (which may be a mobile phone, a computer, a server, an air conditioner, or a network device) to implement methods described in the embodiments of the present disclosure.

The present disclosure is described by referring to flowchart and/or block diagram of the method, the device (system), and the computer program product according to the embodiments of the present disclosure. It should be understood that each process and/or block and combinations of the processes and/or blocks of the flowcharts and/or the block diagrams may be implemented in the form of computer program instructions. These computer program instructions may be provided to a general purpose computer, a special purpose computer, an embedded processor or a processor of other programmable data processing device to form a machine, such that devices for implementing functions specified by one or more flows in the flowchart and/or one or more blocks in the block diagram may be generated by executing the instructions with the processor of the computer or other programmable data processing device.

The computer program instructions may also be stored into a computer-readable memory capable of guiding the computer or other programmable data processing equipment to work by specific means, so that the instructions stored into the computer-readable memory can be provided to produce a product of an instruction device. The instruction device is configured to achieve the functions specified in one or more processes in the flowchart and/or one or more blocks in the block diagram.

These computer program instructions can also be loaded onto the computer or the other programmable data processing device so that a series of operational operations are performed on the computer or the other programmable data processing device to create a computer implemented process so that the instructions executed on the computer or the other programmable data processing device provide operations for performing the functions specified in the flow(s) of the flowchart and/or the block(s) of the block diagram.

Described above is the preferred embodiments of the present disclosure are illustrative only rather than limiting the scope of the present disclosure, all the equivalent structure or process changes made according to the description and accompanied drawings of the present disclosure, or the direct or in direct applications in other related fields, should fall into the scope of protection of the present disclosure.

1. A method for correcting a placement error of a photomask, comprising:
acquiring an exposure offset during a wafer exposure after photomask manufacture is completed, wherein the wafer exposure is a process of forming a circuit pattern on a wafer surface by exposure; and
determining a compensation offset for subsequent photomask manufacture according to the exposure offset, to correct a placement error of a photomask,
wherein the compensation offset and the exposure offset are vector values that are equal in value and opposite in direction.

2. The method according to claim 1, wherein acquiring the exposure offset during the wafer exposure comprises:
acquiring overlay error data during the wafer exposure; and
acquiring the exposure offset by fitting the overlay error data.

3. The method according to claim 2, wherein the overlay error data comprises overlay error data of all location points on a wafer.

4. A method for manufacturing a photomask, applied to a scanner for manufacturing the photomask, the method comprising:
receiving a compensation offset for photomask manufacture, wherein the compensation offset and an exposure offset during a wafer exposure are vector values that are equal in value and opposite in direction, a wafer exposure is performed after a previous photomask manufacture is completed, and the wafer exposure is a process of forming a circuit pattern on a wafer surface by exposure; and
manufacturing a photomask by taking the compensation offset as an exposure reference.

5. A device for correcting a placement error of a photomask, comprising a memory and a processor, wherein the memory is configured to store instructions, and the processor is configured to execute the instructions stored in the memory to:
acquire an exposure offset during a wafer exposure after photomask manufacture is completed, wherein the wafer exposure is a process of forming a circuit pattern on a wafer surface by exposure; and
determine a compensation offset for subsequent photomask manufacture according to the exposure offset, to correct a placement error of a photomask,
wherein the compensation offset and the exposure offset are vector values that are equal in value and opposite in direction.

6. The device according to claim 5, wherein the processor is configured to execute the instructions stored in the memory to acquire overlay error data during the wafer exposure, and acquire the exposure offset by fitting the overlay error data.

7. The device according to claim 6, wherein the overlay error data comprises overlay error data of all location points on a wafer.

8. A device for manufacturing a photomask, comprising a memory and a processor, wherein the memory is configured to store instructions, and the processor is configured to execute the instructions stored in the memory to execute the method for correcting the placement error the photomask according to claim 1.

9. A terminal device, comprising a memory, a processor and a transceiver, wherein the memory is configured to store instructions, the transceiver is configured to communicate with another device, and the processor is configured to execute the instructions stored in the memory, so that the terminal device executes the method for correcting the placement error of the photomask according to claim 1.

10. A non-transitory computer readable storage medium, wherein the computer readable storage medium stores a computer executable instruction, and the computer is configured to execute, when executing the computer executable instruction, the method for correcting the placement error of the photomask according to claim 1.

11. A computer program product, comprising a computer program, wherein the computer program, when executed by a processor, causes the processor to implement the method for correcting the placement error of the photomask according to claim 1.

12. The method according to claim 3, wherein acquiring the exposure offset by fitting the overlay error data comprises:
minimizing a difference between the overlay error data for all the location points on the wafer surface.

13. The method according to claim 3, wherein the overlay error data for each location point is or is not equal.

14. The method according to claim 1, further comprising one of:
displaying the compensation offset on a screen of a terminal device;
transmitting the compensation offset to an electronic device in an available communication manner.

15. The method according to claim 4, wherein manufacturing the photomask by taking the compensation offset as the exposure reference comprises:
manufacturing the photomask by controlling a placement position of the photomask to be offset by the compensation offset during the photomask manufacture.

16. The device according to claim 7, wherein the processor is configured to execute the instructions stored in the memory to minimize a difference between the overlay error data for all the location points on the wafer surface.

17. The device according to claim 7, wherein the overlay error data for each location point is or is not equal.

18. The device according to claim 5, further configured to:
display the compensation offset on a screen of a terminal device; or
transmit the compensation offset to an electronic device in an available communication manner.

19. A terminal device, comprising a memory, a processor and a transceiver, wherein the memory is configured to store instructions, the transceiver is configured to communicate with another device, and the processor is configured to execute the instructions stored in the memory, so that the terminal device executes the method for correcting the placement error of the photomask according to claim 4.

20. A non-transitory computer readable storage medium, wherein the computer readable storage medium stores a computer executable instruction, and the computer is configured to execute, when executing the computer executable instruction, the method for correcting the placement error of the photomask according to claim 4.
